(19) United States
(12) Patent Application Publication
(10) Pub. No.: US 2009/0224763 A1
(43) Pub. Date: Sep. 10, 2009

(54) METHOD AND APPARATUS FOR LOSSLESS OR LOW LOSS COUPLING FOR MANY CHANNEL RF COIL ARRAYS

(75) Inventor: G. Randy Duensing, Gainesville, FL (US)

Correspondence Address: SALIWANCHIK LLOYD & SALIWANCHIK;A PROFESSIONAL ASSOCIATION, PO Box 142950, GAINESVILLE, FL, 32614, US

(73) Assignee: Koninklijke Philips Electronics N.V., BA Eindhoven (NL)

(21) Appl. No.: 12/330,358

(22) Filed: Dec. 8, 2008

Related U.S. Application Data
(60) Provisional application No. 61/005,657, filed on Dec. 6, 2007.

(51) Int. Cl. G01R 33/34

(52) U.S. Cl. 324/318

(57) ABSTRACT

Embodiments of the invention relate to methods and apparatus for lossless, or low loss, coupling for many channel RF coil arrays. Non-invertible noise can be converted to invertible noise. Specific embodiments pertain to methods and apparatus for magnetic resonance imaging (MRI) with many channel RF coil arrays. Specific embodiments pertain to methods and apparatus for matching one or more preamplifiers to associated coils in an MRI array and tuning the MRI coil array. Embodiments of the invention can incorporate matching of the coil to the impedance of the preamplifier.

### CROSS-REFERENCE TO RELATED APPLICATION(S)

The present application claims the benefit of U.S. Provisional Application Ser. No. 61/005,657, filed Dec. 6, 2007, which is hereby incorporated by reference herein in its entirety, including any figures, tables, or drawings.

Embodiments of the invention relate to methods and apparatus for lossless, or low loss, coupling for many channel RF coil arrays. Specific embodiments pertain to methods and apparatus for magnetic resonance imaging (MRI).

### BACKGROUND OF INVENTION

The current trend in Magnetic Resonance Imaging (MRI) is to employ an ever greater number of radio frequency (RF) coils. Presently, the standard clinical MRI systems have 32 channels available for RF coil acquisition. With the advent of 32 channel clinical MR systems, and research systems with higher channel counts, many RF coil products and prototypes have been constructed to take advantage of the receiver hardware infrastructure. It has become clear that, in many cases, the signal-to-noise ratio (SNR) suffers if the coil element count is very high and the unit coils are small (Boskamp, E. B. et al., Proc. ISMRM, 2007, p. 1048, and Wiggins, G. C. et al. Proc. ISMRM, 2005, p. 671). This is particularly noticeable in volumetric arrays when compared with volume coils near the center of the array volume. The causes of these losses in SNR have been postulated to include unnecessary conductor losses, non-invertible noise coupling, shielding effects of many channels, and cable current losses (Wiggins, G. C. et al., Proc. ISMRM, 2007, p. 243). It would be advantageous to eliminate any or all of these effects.

Non-invertible noise coupling is a significant effect in SNR loss in many channel RF coil arrays. (Reykowski, Arne, et al., Rigid Signal-to-Noise Analysis of Coupled MRI Coils Connected to Noisy Preamplifiers and the Effect of Coil Decoupling on Combined SNR, Proc. ISMRM, 2000.) The state-of-the-art method for decoupling coil arrays utilizes a preamplifier that is severely power mismatched to the coil element (Roemer, et al.). This approach reduces the effect of mutual inductance by reducing the current in each coil element. This reduction is a result of a large impedance, which is usually primarily resistive, inserted into the coil loop as a result of attaching the preamplifier. While this method does not severely damage the SNR of a given coil, as the noise figures of the preamplifiers are typically less than 1 dB, it does lower the combined SNR (Signal to Noise Ratio) of an array of coil elements due to some preamplifier noise coupling from one element to another by means of shared impedances. For the coil element incorporating the preamplifier, the noise from the preamplifier is low with respect to the coil signal. However, for a second coil element that is coupled to the first the noise from the first coil's preamplifier can be dominant with respect to the noise energy coupled from the first coil to the second The same impedance that lowers the current and, thus, the inductive decoupling, becomes the dominant source of noise current that will circulate in the coil element. The method of utilizing a preamplifier that is power mismatched to the coil has been extremely successful in allowing effective multi-channel arrays. As the mismatch increases and the effective resistance in the loop increases, the coupling monotonically decreases. However, with increasing mismatch the relative percentage of noise from the preamplifier coupled to other elements in the array increases. The noise coupled from a first coil element to a second coil element is very different from the noise that emerges from the preamplifier on the first coil element. This fact makes complete removal of the effect of noise coupling impossible.

In this way, the use of a preamplifier that is power mismatched to the coil represents a limitation for many channel coil arrays. In a modern 32 element coil, a given element may have a small but measurable coupling effect with 20 or more other elements. Each of the coupled noise contributions from the preamplifiers are uncorrelated, since the noise sources associated with each preamplifier are uncorrelated from one preamplifier to another. Therefore, each loss in SNR adds approximately linearly with coupled noise power. The result is that mutual impedances that are adequate for a 4, or even 8 channel array, may not be sufficient for 32 or more small coil elements.

As discussed above, with multi-element systems, each coil element typically has a corresponding preamplifier. The preamplifier receives the signal from the coil and outputs a signal for processing by a receiver. In this way, the signal outputted to the receiver includes noise due to the resistance of the coil. This is because resistance generates thermal noise. Inductive coupling with nearby coils can increase the total noise output to the receiver from the preamplifier associated with the coil. Current approaches to reduce SNR losses can fail when coupling is strong and/or many coil elements are coupled. It appears that array coils with 32 or more elements are at a point where the effects of noise coupling from the preamplifiers via the coil element mutual impedance becomes significant.

Roemer et al. (Mag. Res. Med. 16, 192-225, 1990) demonstrated a basic inductive decoupling strategy. In addition also Roemer et al. described methods for simultaneously acquiring and subsequently combining NMR signals from a multitude of overlapping and closely positioned RF coil elements. For the NMR phased array taught by Roemer et al., adjacent coils are overlapped in order to minimize mutual inductance and each coil is connected to a highly impedance mismatched preamplifier producing a high impedance in the coil element to reduce the effect of mutual inductance between the coil elements that are not overlapped. Roemer et al. taught that the greater the impedance mismatch between coil and preamplifier and therefore the greater the impedance presented to the coil element, the greater the reduction of the effects of mutual impedances between the coil elements.

Since the introduction of this inductive decoupling technique by Roemer et al. efforts have been made to further increase the impedance mismatch between the preamplifier and the coil element. The typical preamplifiers used in current MRI systems have an mismatch ratio of approximately 50. Where the mismatch ratio is defined as the input impedance of the preamplifier divided by the impedance which is presented to the preamplifier by the coil element. This means that a coil element with an impedance of 2 ohms real can see approximately 100 ohms from the preamplifier. This dramatically increases the effective loop impedance from 4 ohms, for the powermatch preamplifier case which includes 2 ohms from the coil element and 2 ohms from the power matched amplifier, to 102 ohms using the impedance mismatched preamplifier. This results in a drop in voltage, induced in a second coil element through mutual inductance by a factor of approximately 25 for a constant voltage source in the first coil element. This is very effective for moderate inductive coupling between a relatively small number of coupled loops where the primary source of the coupled noise can be depicted as voltage sources in the loops. However, if the coupling is quite strong and/or the number of elements coupled is high, there is at least one aspect of the technique that can be problematic. The noise voltage that is transferred from this loop with effective impedance of 102 ohms originates mostly from the 100 ohms presented to the coil element by the preamplifier and not from the coil or sample. In the input referred noise model for preamplifiers, by Rothe and Dahlke (Rothe, H., Dahlke, W., Theory of Noisy Fourpoles, Proceedings of the Ire, June 1956, pp. 811-818.), the noise from the preamplifier can be modeled as a noise voltage source and a noise current source. While the noise coupling due to the preamplifier noise voltage source can be reduced by means of preamplifier decoupling, the coupling due to the preamplifier noise current source actually will increase with improved preamplifier decoupling. This effect can also be explained using a wave model that Penfield derived from the Rothe and Dahlke model. In this model by Penfield, there are two uncorrelated noise waves on the input side of the preamplifier. One noise wave is propagating towards the source (in our case the coil) where it is totally absorbed for the case of noise matching. The other wave is propagating towards the preamplifier where it is partially reflected due to the preamplifier input impedance. In case of noise matching only the wave propagating towards the preamplifier will add to the noise at the preamplifier output. Since preamplifier decoupling requires a high reflection coefficient between coil and preamplifier most of the noise wave propagating towards the preamplifier will be reflected at the preamplifier input and therefore also coupled to other coil elements. This form of noise coupling is also described in (Papoulis, A., Wave Representation of Amplifier Noise, Ire Transactions on Circuit Theory, pp. 84-86.) and (Duensing “Maximizing signal to noise ratio in the presence of coil coupling” J. Magn. Res. 111:230-235, 1996”). The result of this problem is that substantial coupling between many coils can result in unrecoverable losses in Signal-to-Noise ratio (SNR).

The coupling of noise and signal between two coils with low input impedance preamplifiers attached is very small. Suppose that both coils in FIG. 10 are independently tuned to the same resonant frequency

$${ω}_{0} = \frac{1}{\sqrt{{L}_{coil} {C}_{coil}}}$$

Without the second coil element present, the total impedance of the primary loop as viewed at terminal A is given by R₁. With the second coil present and connected to a preamplifier of input impedance Rᵢₙ⁽²⁾ the impedance Z_{A} as viewed from the terminals of the primary coil element is then given by

$${Z}_{A} = {R}_{coil}^{( 1 )} + \frac{{ω}_{0}^{2} {L}^{2} {k}^{2}}{{R}_{coil}^{( 2 )} + {R}_{in}^{( 2 )}} \qquad ( 3 )$$

The second term is due to the mutual impedance between the two coil elements. If either the mutual impedance is made zero or the input impedance of the preamplifier is made very large, this second term approaches zero and the resultant impedance R_{coil}⁽¹⁾ that of a single isolated coil at resonance.

The NMR signal transferred between two coils can be determined by the pen circuit voltage V_{A} as viewed at terminal A, resulting in the following:

$${V}_{A} = {V}_{coil}^{( 1 )} + {V}_{coil}^{( 2 )} \frac{{ω}_{0} {L}_{coil} k}{{R}_{coil}^{( 2 )} + {R}_{in}^{( 2 )}} \qquad ( 4 )$$

Accordingly, if the mutual inductance is very low or the preamplifier input impedance is very high, the open circuit voltage V_{A} approaches the voltage received by the isolated primary coil element.

It therefore seems that increasing the input impedance of the preamplifier in the secondary coil element reduces the effect of mutual inductance on the signal output of the primary coil in the same way as reducing the mutual inductance does. However, the model of FIG. 10 does not yet include the noise model for the preamplifier in the secondary coil element. It will be shown next that considering the full noise model for the preamplifier has a significant impact on the performance of preamplifier decoupling (i.e. Rᵢₙ⁽²⁾→∞).

FIG. 11 shows the complete input referred noise model for the second preamplifier as well as the equivalent circuit for the two coupled coil elements. Using this input referred noise model, the open circuit voltage V_{A} as viewed at terminal A becomes

$${V}_{A} = {V}_{coil}^{( 1 )} + [ {V}_{coil}^{( 2 )} + {v}_{n}^{( 2 )} ] \frac{{ω}_{0} {L}_{coil} k}{{R}_{coil}^{( 2 )} + {R}_{in}^{( 2 )}} + j {i}_{n}^{( 2 )} \frac{{ω}_{0} {L}_{coil} {kR}_{in}^{( 2 )}}{{R}_{coil}^{( 2 )} + {R}_{in}^{( 2 )}}$$

Once again, if the mutual coupling k approaches 0 the open circuit voltage V_{A} approaches that received by the isolated primary coil element. However, if the mutual inductance cannot be removed and, instead, preamplifier decoupling in (Rᵢₙ⁽²⁾→∞) is employed to decrease the effects of mutual coupling than the open circuit voltage V_{A} will be

V_{A}=V_{coil}⁽¹⁾+(jω₀L_{coil}k)·iₙ⁽²⁾

This means that there will be noise coupled from preamplifier 2 to preamplifier 1 as long as there is a significant mutual inductance ωL_{coil}k. This noise coupled from one coil element to another reduces the total combined SNR achievable with array coils when compared to the case where there is no mutual impedance between the coil elements present (see also Reykowski, Wang, “Rigid Signal-to-Noise Analysis of Coupled MRI Coils Connected to Noisy Preamplifiers and the Effect of Coil Decoupling on Combined SNR”, Proceedings of ISMRM 2000).

Still assuming that Rᵢₙ⁽²⁾→∞ the voltage V_{B} as viewed at terminal B is

V_{B}=V_{coil}⁽²⁾+vₙ⁽²⁾+R_{coil}⁽²⁾·iₙ⁽²⁾=S_{coil}⁽²⁾+(N_{coil}⁽²⁾+vₙ⁽²⁾+R_{coil}⁽²⁾·iₙ⁽²⁾)

where S_{coil}⁽²⁾ is the MRI signal induced into coil element 2 and N_{coil}⁽²⁾ is the random thermal noise voltage due to losses in the sample and the coil. Since the preamplifiers typically add very little noise, most of the noise in V_{B} will be due to sample and coil:

$$\sqrt{〈 {\vert {N}_{coil}^{( 2 )} \vert}^{2} 〉} >> \sqrt{ 〈 {\vert {v}_{n}^{( 2 )} + {R}_{coil}^{( 2 )} \cdot {i}_{n}^{( 2 )} \vert}^{2} 〉}$$

For a preamplifier with a noise figure of 0.5 dB, only 5% of the RMS noise at the output is due to the preamplifier, 95% is due to coil and sample losses. This also means that the noise (jω₀L_{coil}k)·iₙ⁽²⁾ coupled from coil element 2 to coil element 1 is highly uncorrelated from the noise (N_{coil}⁽²⁾+vₙ⁽²⁾+R_{coil}^{(2)·i}ₙ⁽²⁾) that is measurable at the output of preamplifier 2. This means that the mechanism due to which noise emanating from a preamplifier attached to a second coil element and coupling into a first coil element is not invertible by post processing all output signals from all coil elements.

Accordingly, there is a need for a method and apparatus to reduce noise coupling between coils in many channel RF coil arrays.

### BRIEF DESCRIPTION OF DRAWINGS

FIG. 1 shows a constructed pair of coils (roughly 10×12 cm) with a shared leg in accordance with an embodiment of the subject invention.

FIGS. 2A and 2B show standard preamplifier decoupled single channel images using the constructed pair of coils of FIG. 1 with poor isolation for noise balanced channel 1 and channel 2, respectively.

FIGS. 3A and 3B show the output for the standard preamplifier decoupled single channel with a 90 degree phase shifter in front of the preamplifiers using the constructed pair of coils of FIG. 1 for noise balanced channel 1 and channel 2, respectively.

FIG. 4 shows a loop mode from an eigen-process using the constructed pair of coils of FIG. 1 in accordance with an embodiment of the subject invention.

FIG. 5 shows a butterfly mode using the constructed pair of coils of FIG. 1 in accordance with an embodiment of the subject invention.

FIG. 6 shows a loop mode from an eigen-process using the constructed pair of coils of FIG. 1 in accordance with an embodiment of the subject invention.

FIG. 7 shows a butterfly mode using the constructed pair of coils of FIG. 1 in accordance with an embodiment of the subject invention.

FIG. 8 shows the Sum of Squares of the embodiments shown in FIGS. 5-8 after optimized noise whitening for the standard preamplifier decoupled case.

FIG. 9 shows the Sum of Squares of the embodiments shown in FIGS. 5-8 after optimized nose whitening of the preamplifier super-coupled case.

FIG. 10 shows a circuit model of two coil elements that share a mutual inductance.

FIG. 11 shows a circuit model of two coils that share a mutual inductance including the input referred noise model for the preamplifier attached to the second coil element.

FIG. 12 shows two preamplifiers attached to a single coil element with impedance Z_{coil} where preamplifier 1 has input impedance Zᵢₙ⁽¹⁾ and optimum noise match impedance Zₒₚₜ⁽¹⁾ and preamplifier 2 has input impedance Zᵢₙ⁽¹⁾ and optimum noise match impedance Zₒₚₜ⁽²⁾.

FIG. 13 shows the effect of adding a preamplifier to S₁₁ of one of the loaded coils.

FIG. 14 shows two bottles with circular coil elements surrounding each bottle and oriented coaxially with the other.

FIG. 15 Shows a circuit model for two coupled coils that share a mutual impedance Z_{M} and are attached to preamplifiers that have associated noise voltage sources Vₙ⁽ⁱ⁾ and noise current sources iₙ⁽ⁱ⁾.

FIG. 16 shows a coronal image of bottles shown in FIG. 14 using coupled coils at 4.5″ separation.

FIG. 17 shows SNR versus distance between loops for three cases: (Case 1) all 4 preamplifiers used for reconstruction, (Case 2) two extra preamplifiers are attached to coil but not powered, and (Case 3) standard 2 preamplifier decoupling strategy.

FIG. 18 shows a modified equivalent noise model for two preamps connected to a single coil.

FIG. 19 shows the input inferred noise model.

FIG. 20 shows a schematic of an embodiment of the subject invention having two coils, with each coil having two preamplifiers.

### DETAILED DISCLOSURE

Embodiments of the invention relate to methods and apparatus for lossless, or low loss, coupling for many channel RF coil arrays. Non-invertible noise can be converted to invertible noise. Specific embodiments pertain to methods and apparatus for magnetic resonance imaging (MRI) with many channel RF coil arrays. Specific embodiments pertain to methods and apparatus for matching one or more preamplifiers to associated coils in an MRI array and tuning the MRI coil array. Embodiments of the invention can incorporate matching of the coil to the impedance of the preamplifier.

Embodiments of the invention are advantageous for use with large channel counts. In a specific embodiment, the subject technique is applied to an array having at least 32 coils. In another specific embodiment, the subject technique is applied to an array having at least 64 coils. Another advantage of the subject invention is its use for unusual coil configurations.

Embodiments of the invention relate to a method of matching a plurality of coupled RF coils associated with a particular reconstruction algorithm. In an embodiment of the invention, inductive coupling can be permitted to occur between channels. The coupling, in moderate amounts, is not detrimental as long as it is measurable. In this embodiment, the noise in the channels can be made linearly related to the noise transferred between the channels. If linearity, preferably strict linearity, occurs, then inversion can be accomplished. Accurate measurement of the coupling signals permits algebraic inversion.

In another embodiment, referring to FIG. 12, a preamplifier with optimum noise match impedance Zₒₚₜ⁽¹⁾ and high input impedance Zᵢₙ⁽¹⁾ at the coil terminals as taught by Roemer et al., can be employed. In this embodiment, a second preamplifier with optimum noise match impedance Zₒₚₜ⁽²⁾ and low input impedance Zᵢₙ⁽²⁾ is connected in series to the first preamplifier. It can be shown that the SNR obtainable from a weighted combination of the output signals is the same as the SNR obtained from a single noise matched preamplifier with otherwise identical noise parameters as long as Zₒₚₜ⁽¹⁾+Zₒₚₜ⁽²⁾=Z_{coil}.

The primary reason why the preamplifier decoupling method was developed by Roemer is that the coupling between coils can result in multiple modes (N coils produce N modes), generally at different frequencies. Using the preamplifier decoupling method by Roemer (i.e., providing a high impedance to the input terminals of each coil) reduces the effects of mode coupling between the coil elements.

Without preamplifier decoupling two coupled identical coils can have two associated modes at different frequencies. In an embodiment, the frequencies of the coils can be adjusted to bring one of the modes to the Larmor frequency. In this embodiment, bringing one of the modes to the Larmor frequency permits a good match and noise figure with the preamplifiers. This results in both channels being received by the system having nearly identical characteristics, i.e., both preamplifiers receive signal from the shared coupled mode in the same way that the two preamplifiers in FIG. 12 receive signal from a shared coil element. Maximum SNR can be extracted from the mode if

Zₒₚₜ⁽¹⁾+Zₒₚₜ⁽²⁾=Z_{Mode}

Where Zₒₚₜ⁽¹⁾ and Zₒₚₜ⁽²⁾ are the optimum noise match impedances for the two preamplifiers and Z_{Mode} is the mode impedance seen by one of the two preamplifiers if the other preamplifier is replaced with a short circuit.

In one embodiment, if the splitting between modes is not extremely large compared to the Q factors of the coils, then the behavior of the two ports at one of the resonant modes will not be exactly the same. For example, the two coupled coils referred to can have a mode that is associated with co-rotating current and a mode associated with counter-rotating current. In this embodiment, if the coil is tuned such that the Larmor frequency is at the co-rotating mode, for example, one would expect the outputs of both coils would be identical whether loop 1 was excited or loop 2 was excited. However, because the other mode is not infinitely far away and the Q's are not infinite, the output of loop 1, when loop 1 is driven, will generally be at least slightly higher than the output of loop 2. In addition, the phase will not be exactly the same. This small difference can be important with respect to the embodiment of the invention. If all of the possible modes are represented in the outputs of all of the coils, then it would generally be possible to reconstruct all of the modes from the outputs. To the extent that the noise coupling and signal coupling are identical, the inversion based on noise whitening also creates signal distributions associated with the resistive eigen-modes of the array. Standard (noise covariance) optimal reconstruction, as described in Roemer et al and Pruessmann et al (MRM 1999 SENSE: Sensitivity Encoding for Fast MRI), can be performed on the outputs of the coupled coils to produce the final image.

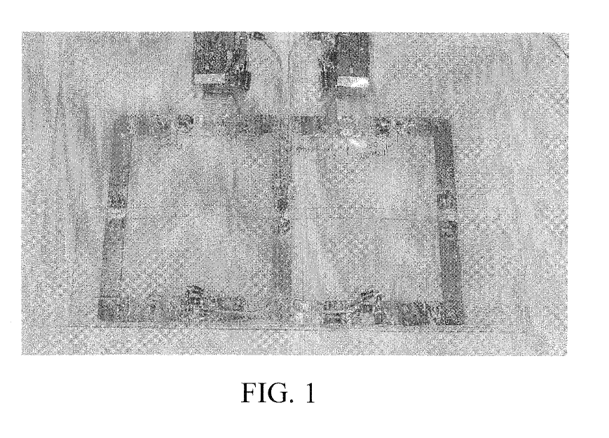

Referring to FIG. 1, a pair of coil elements is shown with a shared leg between them, where each coil is about 10 cm×12 cm. A capacitor was placed in the shared leg to provide a means of adjusting the effective mutual reactance. Isolation at 64 MHz was produced with about 143 pF in the leg. The coil was adjusted to produce a certain loss measured in the following way. One coil was driven through its input and the current was measured with a field probe. The isolation was adjusted by decreasing the capacitance in the leg, such that there was approximately a 2 dB difference in the current when the preamplifier was attached (with a tuned input) and when the coil was physically opened by lifting a capacitor. The capacitance was approximately 76 pF, suggesting a mutual impedance of about 15 ohms or so, whereas each coil needed approximately 150 ohms of capacitance to tune it to resonance. The coupling coefficient “k” is therefore around 0.1 and a predicted splitting is around 6 MHz. Bench measurements show a splitting of about 7 MHz. The tuning was adjusted such that the higher frequency mode (butterfly) was at 64 MHz and the lower (large loop) was at 56.4 MHz. The preamplifiers provided a low resistance to the coil elements, which had a value of about 1/50 of the resistance of the isolated coil elements. This configuration provides the worst case isolation between the coil elements and it appears that both preamplifiers would see the same butterfly mode. It further appears that there would not be much advantage in using two preamplifiers instead of a single preamplifier.

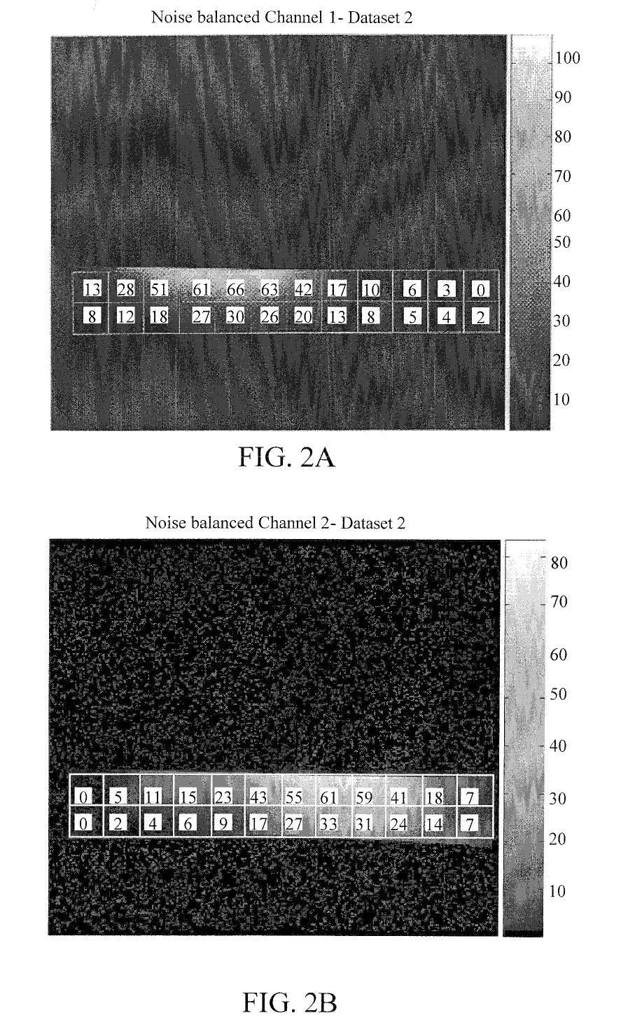

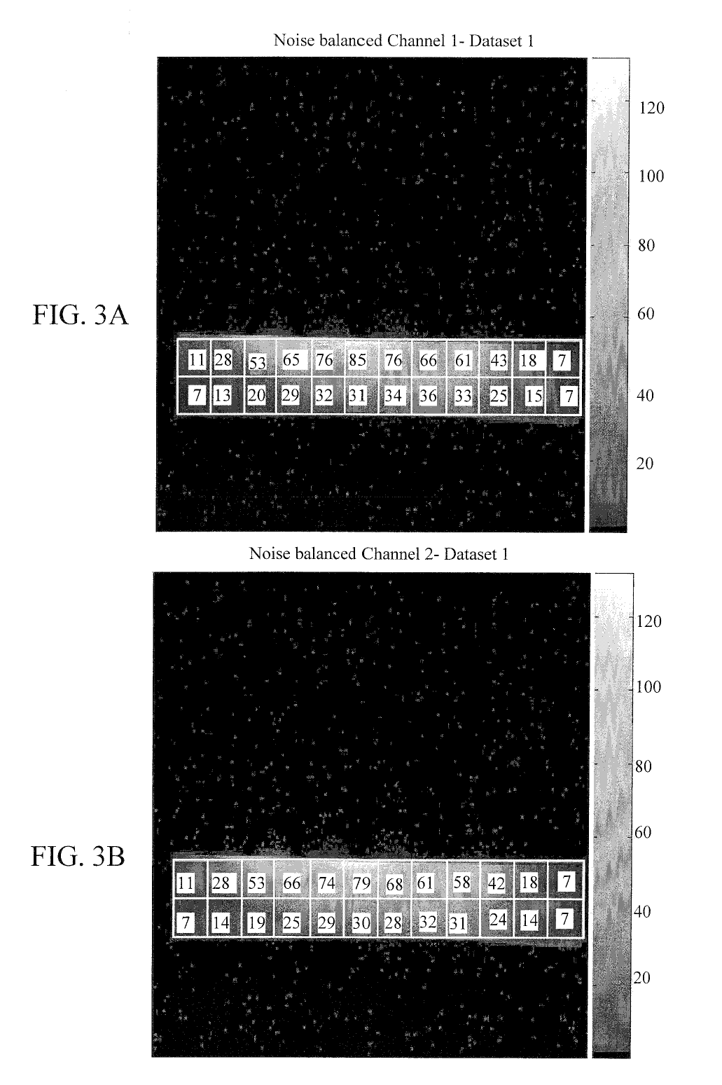

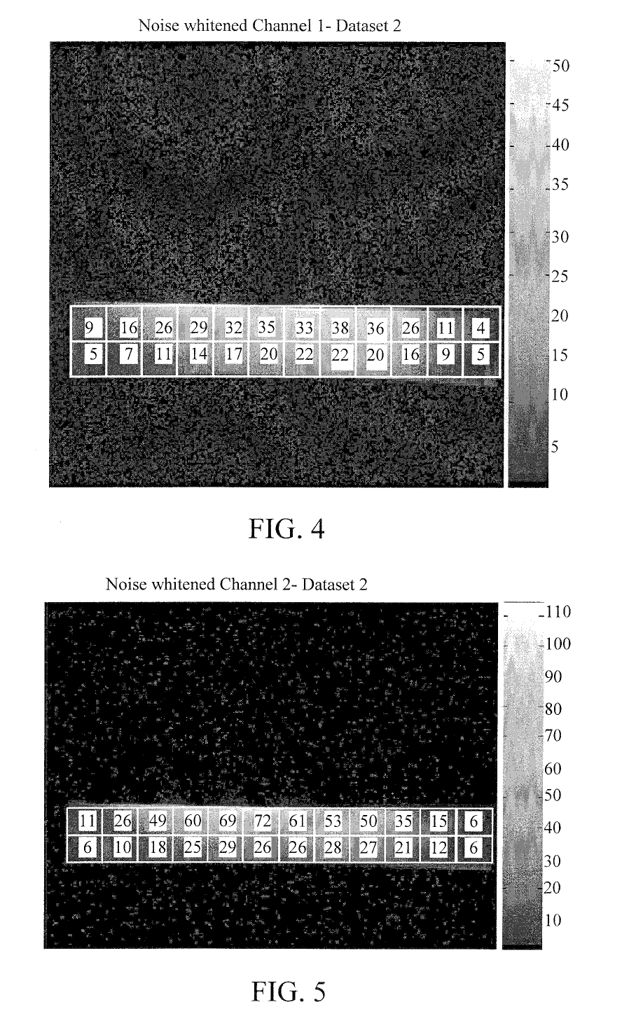

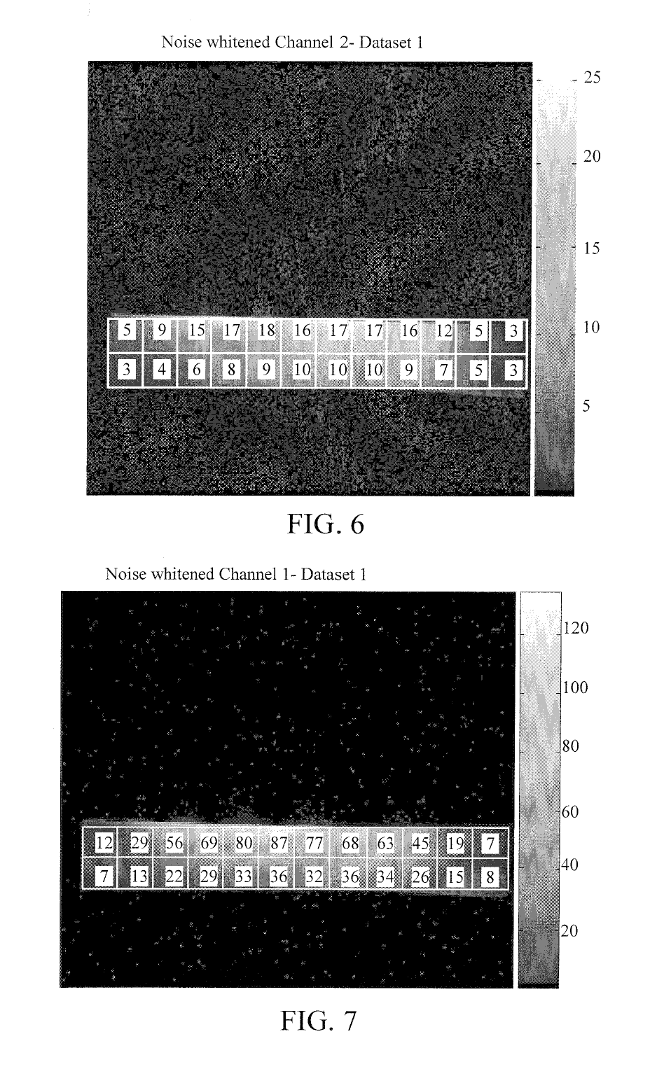

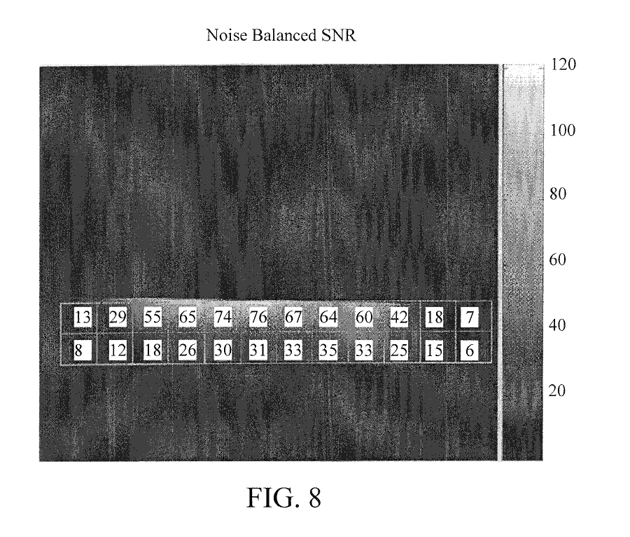

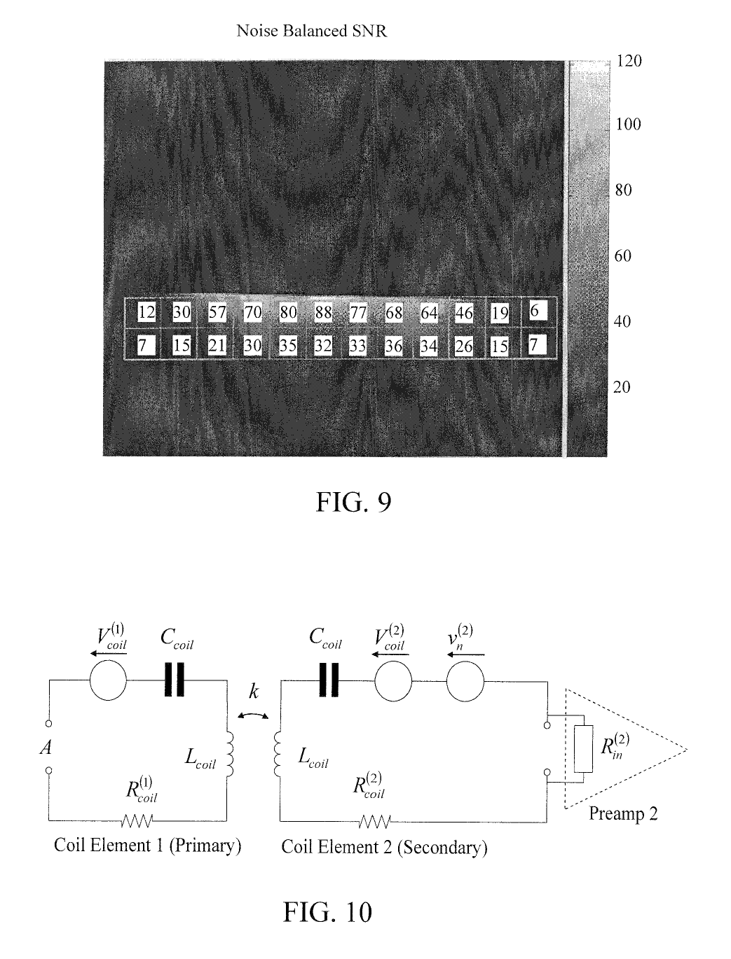

FIGS. 2-9 show MR results from this coil in the preamplifier decoupled case and the super-coupled case. FIGS. 2A and 2B show the individual images using preamplifier decoupling. In this case both preamplifiers provided a high resistance to the coil elements, which was about a factor 50 higher than the resistance of the isolated coil elements. FIGS. 3A and 3B show the outputs of the same two preamplifiers when a 90 degree phase shifter is added in front of the preamplifiers. In this case, the input impedance of the preamplifiers is about 1/50 of the isolated coil element resistance. The images for both cases look almost, but not quite, identical. The noise output of both preamplifiers should be very strongly correlated in the same way that the signals are correlated. The next step is to whiten the noise in both cases. The new individual images are shown in FIGS. 4 and 5. FIG. 4 shows the loop mode from the eigen-process and FIG. 5 shows the butterfly mode. The loop mode appears to be better at depth but the butterfly mode appears to be better for close. FIGS. 6 and 7 show the same eigenmodes as FIG. 4 and FIG. 5, but because the loop mode was 7.5 MHz off frequency, its contribution is weak, whereas the butterfly mode is about 20% better because of the lossless manner of attaching the preamplifier. The combined Sum of Squares (SoS) images area are shown in FIGS. 8 and 9. FIG. 8 shows the Sum of Squares image area after optimized noise whitening for standard preamplifier decoupled case. FIG. 9 shows the Sum of Squares image area after optimized nose whitening of preamplifier super-coupled case.

The process of using preamplifier decoupling (i.e., Rᵢₙ⁽²⁾→∞) can be lossy. When the mutual impedance between coil elements is strong, the noise transferred between coil elements is associated with the noise emanating from the front end of the preamplifiers and not the thermal noise from losses in the coil elements and sample. This is due to the fact that the current produced in a coil element from thermal noise due to losses in coil and sample will be significantly reduced through the use of preamplifier decoupling methods. However, the part of the noise current in a coil element that is due to the preamplifier front end is not a function of the total impedance of the combination of coil and preamplifier but rather a function of the magnitude of reflection coefficient between coil and preamplifier (see ref. Penfield). This fact prevents linear inversion and correction of the noise coupled between coil elements. However, when using the opposite strategy (i.e., Rᵢₙ⁽²⁾→0), which we may term “preamplifier super-coupling”, the noise coupled between the two preamplifiers will be mainly due to losses in the coil elements and the sample. Moreover, the noise at the output of a preamplifier will be dominated by a component that is a linear function of the noise current on the attached coil element.

The assumption is that the SNR of the primary mode received with two preamplifiers can be recovered to an extent that is similar to receiving the same mode with a single preamplifier. At this point the question is whether additional signal received from the other mode(s) allows to increase the SNR even further or whether these mode(s) are too far off in frequency and, thus, too weak to be adequately sampled. For the specific case demonstrated, the loop mode was at 56.4 MHz, 7.5 MHz away and the loss compared to the standard decoupled case was severe, such that only about 50% of the SNR of that mode was obtained.

Specific embodiments involve a method and apparatus for converting non-invertible noise to invertible noise. Converting non-invertible noise to invertible noise can eliminate an impediment to the improvement of many channel arrays. Embodiments of the subject method for converting non-invertible noise to invertible noise to address non-invertible noise coupling can be used in situations where coupling is permissible but measurable. Accurate measurement of the coupling signals can permit algebraic inversion of the noise. Such algebraic inversion can be accomplished via, for example, optimal reconstruction, utilizing noise correlation measurements.

Consider the two coil system of FIG. 15 with and without coupling. In this equivalent circuit, the coupling is created by a mutual impedance Z_{M}. Without coupling (Z_{M}=0) the two channels of data can be represented as:

$$\begin{matrix}\frac{{V}_{in}^{( 1 )}}{A} = {S}^{( 1 )} + {N}^{( 1 )} + {v}_{n}^{( 1 )} + {Z}_{coil}^{( 1 )} {i}_{n}^{( 1 )} & ( 5 ) \\ and & \\ \frac{{V}_{in}^{( 2 )}}{B} = {S}^{( 2 )} + {N}^{( 2 )} + {v}_{n}^{( 2 )} + {Z}_{coil}^{( 2 )} {i}_{n}^{( 2 )} & ( 6 )\end{matrix}$$

where S⁽¹⁾ and S⁽²⁾ represent the signals for coil element 1 and coil element 2, respectively. N⁽¹⁾ and N⁽²⁾ represent noise that originates within the first and second coil/sample systems, respectively. The noise N⁽¹⁾ originates from, for example, interaction of coil element 1 with the sample, from electronics within coil element 1, and from the coil element 1 conductor. The noise Nf₁=vₙ^{(1)+Z}_{coil}⁽¹⁾ⁱₙ⁽¹⁾ is additional noise, which can be associated with the preamplifier and subsequent receive chain of channel 1.
The factors A and B are a function of the impedances in the network and only affect respective gains but not the resulting SNR's and noise correlations:

$$A = \frac{{Z}_{in}^{( 1 )}}{{Z}_{in}^{( 1 )} + {Z}_{coil}^{( 1 )} + \frac{{( {Z}_{M} )}^{2}}{{Z}_{in}^{( 2 )} + {Z}_{coil}^{( 2 )}}} B = \frac{{Z}_{in}^{( 2 )}}{{Z}_{in}^{( 2 )} + {Z}_{coil}^{( 2 )} + \frac{{( {Z}_{M} )}^{2}}{{Z}_{in}^{( 1 )} + {Z}_{coil}^{( 1 )}}}$$

In the presence of coupling the two channels of data can be represented as:

$$\begin{matrix}\frac{{V}_{in}^{( 1 )}}{A} = {S}^{( 1 )} + {N}^{( 1 )} + {v}_{n}^{( 1 )} + {Z}_{coil}^{( 1 )} {i}_{n}^{( 1 )} - {k}_{21} [ \begin{matrix}{S}^{( 2 )} + {N}^{( 2 )} + {v}_{n}^{( 2 )} + \\ {Z}_{coil}^{( 2 )} {i}_{n}^{( 2 )}\end{matrix} ] + {Z}_{M} {i}_{n}^{( 2 )} & ( 7 ) \\ and & \\ \frac{{V}_{in}^{( 2 )}}{B} = {S}^{( 2 )} + {N}^{( 2 )} + {v}_{n}^{( 2 )} + {Z}_{coil}^{( 2 )} {i}_{n}^{( 2 )} - {k}_{12} [ \begin{matrix}{S}^{( 1 )} + {N}^{( 1 )} + {v}_{n}^{( 1 )} + \\ {Z}_{coil}^{( 1 )} {i}_{n}^{( 1 )}\end{matrix} ] + {Z}_{M} {i}_{n}^{( 1 )} & ( 8 ) \\ With & \\ {k}_{21} = \frac{{Z}_{M}}{{Z}_{in}^{( 2 )} + {Z}_{coil}^{( 2 )}} {k}_{12} = \frac{{Z}_{M}}{{Z}_{in}^{( 1 )} + {Z}_{coil}^{( 1 )}} & \end{matrix}$$

where k₁₂ represents the effective voltage coupling from coil element 1 to coil element 2, and k₂₁ represents the effective voltage coupling from coil element 2 to coil element 1 Equation (7) represents the output from coil element 1 and equation (8) represents the output from coil element 2, when coil elements 1 and 2 are coupled through a shared impedance Z_{M}. Note that with knowledge of k₁₂ and k₂₁ one can eliminate part of the coupled components during post processing by making use of an inversion of the voltage coupling matrix K:

$$K = [ \begin{matrix}1 & - {k}_{21} \\ - {k}_{12} & 1\end{matrix} ]$$

Note also that preamplifier decoupling (Zᵢₙ⁽ⁱ⁾→∞) will make the voltage coupling coefficients vanish. But neither post processing techniques nor preamplifier decoupling will remove the terms in equations (7) and (8) that are due to noise current coupling:

Nf₃=Z_{M}iₙ⁽¹⁾ Nf₄=Z_{M}iₙ⁽²⁾

The ability of using high input impedance preamplifiers to reduce the effects of mutual impedance is inevitably tied to the fact that the output of the coil element is not deteriorated by the inserted high preamplifier input impedance, but the remaining circulating noise current that causes residual coupling to other coil elements is dominated by noise emanating from the preamplifier.

If one could obtain a measurement of Nf₃ and Nf₄, then it would be possible to invert the coupling.

The following approach is designed to obtain some knowledge of Nf₃ and Nf₄ with the objective to reduce the effect of noise coupling between coil elements. In this approach two preamplifiers can be attached to each coil element. The output signals of these preamplifiers can be combined into two modes. The first mode can contain a signal with an SNR equivalent to what would be expected from a single noise matched preamplifier attached to the coil. The second mode can contain noise information that can allow for the reduction of the effect of noise coupled between the elements. This combination can either be done in hardware, software, or by using an optimal reconstruction algorithm (Roemer et al).

FIG. 18 shows an equivalent circuit for two preamplifiers attached to a single coil element.

Preamplifier 1 has input impedance Zᵢₙ⁽¹⁾ and optimum noise match impedance Zₒₚₜ⁽¹⁾, preamplifier 2 has input impedance Zᵢₙ⁽²⁾ and optimum noise match impedance Zₒₚₜ⁽²⁾. It can be shown that the SNR obtainable from a weighted combination (=first mode) of the output signals from both preamplifiers is the same as the SNR obtained from a single noise matched preamplifier with otherwise identical noise parameters as long as Zₒₚₜ⁽¹⁾+Zₒₚₜ⁽²⁾=Z_{coil}.

If preamplifier 1 has a very high input impedance (=preamplifier decoupling) and preamplifier 2 has a very low impedance (=preamplifier super coupling) than the noise current on the coil will be mainly due to the noise current source iₙ⁽¹⁾ of preamplifier 1. It can now be shown that with appropriate weighted combination of the preamplifier outputs a second mode can be created that is proportional to iₙ⁽¹⁾-iₙ⁽²⁾. Knowledge of this second mode should therefore permit the reduction of the effect of noise coupling to other coil elements.

Both i⁽¹⁾ and iₙ⁽²⁾ are inverse proportional to the magnitude of the respective optimum noise match impedances Zₒₚₜ⁽¹⁾ and Zₒₚₜ⁽²⁾.

It therefore follows that for

|Zₒₚₜ⁽¹⁾|<<|Zₒₚₜ⁽²⁾| [symbol] iₙ⁽¹⁾|² [symbol] >> [symbol] iₙ⁽²⁾|²

[symbol]

Under these circumstances the second mode would be very similar to the noise current on the coil element.

The input referred noise model was introduced by Rothe and Dahlke (Proceedings of the IRE 1956 page 811) in 1956. This model consists of a noiseless preamplifier along with a series voltage source and a shunt current source on the input. This is shown in FIG. 19. For this model the preamplifier parameters of minimum noise figure, Fₘᵢₙ, and optimum source impedance, Zₒₚₜ can be written as functions of the inur voltage source Vₙ, the series current source Iₙ and the correlation between these to signals, γᵣ and γᵢ.

$${F}_{min} = 1 + 2 \sqrt{{R}_{n} {G}_{n}} ( {γ}_{r} + \sqrt{1 - {γ}_{i}^{2}} )$$

$${Z}_{opt} = \sqrt{\frac{{R}_{n}}{{G}_{n}}} [ \sqrt{( 1 - {γ}_{i}^{2} )} + j {γ}_{i} ]$$

FIG. 12 schematically illustrates an embodiment of an implementation of the subject invention. In the embodiment shown in FIG. 12, preamplifier 1 is a standard power mismatched preamplifier, with Zₒₚₜ⁽¹⁾≈Z_{coil} and Zᵢₙ⁽¹⁾≈50*Z_{coil}, that is utilized to reduce the effects of mutual inductance as far as possible. Preamplifier 2, is tuned to have the opposite effect, Zₒₚₜ⁽²⁾<<Z_{coil} and Zᵢₙ⁽²⁾<<Z_{coil}, and represents a negligible change in the impedance of the loop. In this configuration optimum noise figure is achieved for the single coil element when Zₒₚₜ⁽¹⁾+Zₒₚₜ⁽²⁾=Z_{coil}. Because we were not concerned about the noise figure of preamplifier 2 we did not specifically calculate or measure either Zₒₚₜ⁽²⁾ or Zᵢₙ⁽²⁾. Preamplifier 2 can be thought of as a current sensing preamplifier. Since the current in the loop causes inductive coupling, preamplifier 2, acting as an additional sensor can provide information about the signal which is coupled to the other coil elements. In particular information about the noise which coupled to the other coil elements. Since preamplifier 2 causes a very small change in the impedance of the coil element preamplifier 2 can be inserted and removed from the coil element during the experiment.

FIG. 13 shows S₁₁ measurement of the coil, with and without preamplifier 2 attached. The better matching (deeper curve) corresponds to the coil without preamplifier 2 attached The signal and noise is, however, representative of the signal and noise coupled to other channels, with the exception of the noise associated with the noise figure of preamplifier 2.

We can consider the coil shown in FIG. 12 as coil 1 and add second an identical coil element, coil 2. FIG. 20 shows a schematic of an embodiment having two coils, with each coil having two preamplifiers. If we assume that we now have the four signal/noise combinations of equations (7), (8), (9) and (10), it can be seen that by scaling each of the new values by the appropriate coupling factors, we can recover approximately the original uncoupled signals. The approximations have the forms:

$$\begin{matrix}A = \frac{{Z}_{in}^{( 1 , a )}}{{Z}_{in}^{( 1 , a )} + {Z}_{in}^{( 1 , b )} + {Z}_{coil}^{( 1 )} + \frac{{( {Z}_{M} )}^{2}}{{Z}_{in}^{( 2 , a )} + {Z}_{in}^{( 2 , b )} + {Z}_{coil}^{( 2 )}}} \\ B = \frac{{Z}_{in}^{( 1 , b )}}{{Z}_{in}^{( 1 , a )} + {Z}_{in}^{( 1 , b )} + {Z}_{coil}^{( 1 )} + \frac{{( {Z}_{M} )}^{2}}{{Z}_{in}^{( 2 , a )} + {Z}_{in}^{( 2 , b )} + {Z}_{coil}^{( 2 )}}} \\ C = \frac{{Z}_{in}^{( 2 , a )}}{{Z}_{in}^{( 2 , a )} + {Z}_{in}^{( 2 , b )} + {Z}_{coil}^{( 2 )} + \frac{{( {Z}_{M} )}^{2}}{{Z}_{in}^{( 1 , a )} + {Z}_{in}^{( 1 , b )} + {Z}_{coil}^{( 1 )}}} \\ D = \frac{{Z}_{in}^{( 2 , b )}}{{Z}_{in}^{( 2 , a )} + {Z}_{in}^{( 2 , b )} + {Z}_{coil}^{( 2 )} + \frac{{( {Z}_{M} )}^{2}}{{Z}_{in}^{( 1 , a )} + {Z}_{in}^{( 1 , b )} + {Z}_{coil}^{( 1 )}}} \\ {k}_{21} = \frac{{Z}_{m}}{{Z}_{in}^{( 2 , a )} + {Z}_{in}^{( 2 , b )} + {Z}_{coil}^{( 2 )}} {k}_{12} = \frac{{Z}_{m}}{{Z}_{in}^{( 1 , a )} + {Z}_{in}^{( 1 , b )} + {Z}_{coil}^{( 1 )}} \\ {S}_{total}^{( 1 )} = {S}^{( 1 )} + {N}^{( 1 )} {S}_{total}^{( 2 )} = {S}^{( 2 )} + {N}^{( 2 )} \\ {N}_{total}^{( 1 )} = {v}_{n}^{( 1 , a )} + {Z}_{coil}^{( 1 )} {i}_{n}^{( 1 , a )} + {v}_{n}^{( 1 , b )} + {Z}_{coil}^{( 1 )} {i}_{n}^{( 1 , b )} \\ {N}_{total}^{( 2 )} = {v}_{n}^{( 2 , a )} + {Z}_{coil}^{( 2 )} {i}_{n}^{( 2 , a )} + {v}_{n}^{( 2 , b )} + {Z}_{coil}^{( 2 )} {i}_{n}^{( 2 , b )} \\ \begin{matrix}\frac{{V}_{in}^{( 1 , a )}}{A} = {S}_{total}^{( 1 )} + {N}_{total}^{( 1 )} - {k}_{21} [ {S}_{total}^{( 2 )} + {N}_{total}^{( 2 )} ] + \\ {Z}_{m} [ {i}_{n}^{( 2 , a )} + {i}_{n}^{( 2 , b )} ]\end{matrix} \\ \frac{{V}_{in}^{( 1 , b )}}{B} = {S}_{total}^{( 1 )} + {N}_{total}^{( 1 )} - {k}_{21} [ {S}_{total}^{( 2 )} + {N}_{total}^{( 2 )} ] + {Z}_{m} [ {i}_{n}^{( 2 , a )} + {i}_{n}^{( 2 , b )} ] \\ \frac{{V}_{in}^{( 2 , a )}}{C} = {S}_{total}^{( 2 )} + {N}_{total}^{( 2 )} - {k}_{12} [ {S}_{total}^{( 1 )} + {N}_{total}^{( 1 )} ] + {Z}_{m} [ {i}_{n}^{( 1 , a )} + {i}_{n}^{( 1 , b )} ] \\ \frac{{V}_{in}^{( 2 , b )}}{D} = {S}_{total}^{( 2 )} + {N}_{total}^{( 2 )} - {k}_{12} [ {S}_{total}^{( 1 )} + {N}_{total}^{( 1 )} ] + {Z}_{m} [ {i}_{n}^{( 1 , a )} + {i}_{n}^{( 1 , b )} ] & \\ {S}_{1} + {N}_{1} - {k}_{21} N {f}_{3} + N {f}_{1} & ( 11 ) \\ and & \\ {S}_{2} + {N}_{2} - {k}_{12} N {f}_{4} + N {f}_{2} & ( 12 )\end{matrix}$$

In this way, in specific embodiments, the form of the coupling is determined rather than the magnitude of the coupling. The signal plus noise coming out of the coil can be measured, for example via a second preamplifier, instead of further reducing the coupling coefficients. In this way, the noise out of the first preamplifier is measured by the second preamplifier. Accordingly, embodiments of the invention can reduce the need to lower the coupling to the lowest levels. Processing can be accomplished via hardware and/or software.

To test the ability of this second preamplifier to allow near lossless inversion of coupled signal and noise, two coils, were coupled to one another as shown in FIG. 14. Each coil incorporated two preamplifiers, as shown in FIG. 12. The two coils were arranged coaxially with each coil around a different bottle (2.21 liters of distilled water, 4.42 g of CuSO4.5H20, and 4.42 g of NaCl). The separation of the coil planes was adjusted from 6.75 inches down to 3 inches. Images, such as shown in FIG. 16, were taken for each coil separation, with three configurations. In the first configuration (case 1), both preamplifier 1 and preamplifier 2 were operational. In the second configuration (case 2), preamplifier 2 was attached but not powered with supply voltage, and in the third configuration, (case 3), the single standard decoupling preamplifier 1 was used for each coil. The SNR values were measured after noise optimal reconstruction (Roemer et al) of two channels for case 2 and case 3 and four channels for case 1.

In various embodiments, other devices can be used in place of preamplifier 2. In a specific embodiment, an amplifier can be put in the loop so as to be physically attached. In another embodiment, a pick up loop that is not physically attached to the loop, but picks up signal and noise by coupling, can be used. In another embodiment, a small probe coil can be positioned near the loop and the probe coil can have a preamplifier.

FIG. 17 shows a plot of relative SNR for the three cases discussed with reference to FIG. 16, for all coil separations. It can be seen that adding preamplifier 2, without powering it (case 2), produces a loss of SNR of approximately 10 percent due to the added resistance of preamplifier 2. However, when powered and utilized for reconstruction (case 1), the curve changes such that higher SNR is obtained as coupling gets stronger. At the separation point of about 6.75 inches, (where coupling was low), Case 2 and Case 1 coincide, but as the separation drops and the coupling increases, the relative SNR increases and at a separation of about 3.75 inches utilizing preamplifier 2 begins to provide improved SNR over the standard approach (case 3). This demonstrates that adding a preamplifier to measure coil current is beneficial to SNR when coupling causes a reduction of SNR. For particularly strong coupling, even with this additional loss of SNR, the utilization of the signal from the second preamplifier results in a net improvement. Measurement of coil current (including noise from the standard preamplifier) allows for correction of coupling losses. Noise optimal reconstruction can automatically make this correction. The loss associated with preamplifier 2 can be lowered such that the much lower signal from preamplifier 2 (close to 20 dB lower) still allows proper sampling of both signals. The method can also be implemented with many weak coupling pairs of coils. In additional embodiments, the parameters of the system can be adjusted so as to raise the curve in FIG. 16 for case 1 such that case 1 has a higher SNR out past a distance of six inches between loops.

Embodiments of the invention relate to a method and apparatus for imaging using multiple coils, incorporating a measurement of coil current. This measurement of coil current can be valuable in reducing SNR losses due to residual coupling to other coils. Embodiments can be applied to coil configurations where there are many coils with weak coupling. Further embodiments can optimize the impedance of preamplifier 2 and can reduce the loss due to preamplifier 2.

All patents, patent applications, provisional applications, and publications referred to or cited herein are incorporated by reference in their entirety, including all figures and tables, to the extent they are not inconsistent with the explicit teachings of this specification.

It should be understood that the examples and embodiments described herein are for illustrative purposes only and that various modifications or changes in light thereof will be suggested to persons skilled in the art and are to be included within the spirit and purview of this application.

1. An MRI coil configuration, comprising:
a coil element;
a first preamplifier circuit; and
a second preamplifier circuit,
wherein the first preamplifier circuit outputs a first signal,
wherein the second preamplifier circuit outputs a second signal.

2. The MRI coil configuration according to claim 1, further comprising:
at least one additional coil element, wherein each at least one additional coil element comprises a corresponding at least one additional first preamplifier circuit, wherein the at least one preamplifier circuit outputs a corresponding at least one additional first signal.

3. The MRI coil configuration according to claim 2, further comprising:
at least one additional second preamplifier circuit, wherein the at least one additional second preamplifier circuit outputs a corresponding at least one additional second signal.

4. The MRI coil configuration according to claim 3, further comprising:
a means for producing an MRI image from the first signal, the second signal, the at least one additional first signal, and the at least one additional second signal.

5. The MRI coil configuration according to claim 4, wherein the MRI image is produced via optimal reconstruction.

6. The MRI coil configuration according to claim 1, wherein the first preamplifier circuit and the second preamplifier circuit are in series.

7. The MRI coil configuration according to claim 1, wherein the first preamplifier circuit and the second preamplifier circuit are in parallel.

8. The MRI coil configuration according to claim 1, wherein the first preamplifier circuit has a Zₒₚₜ approximately equal to Z_{coil}, where Zₒₚₜ is the impedance the first preamplifier circuit needs to see for optimum noise figure.

9. The MRI coil configuration according to claim 8, wherein the first preamplifier circuit has a Zᵢₙ greater than (10)Z_{coil}, where Z_{coil} is the input impedance of the coil element.

10. The MRI coil configuration according to claim 8, wherein the first preamplifier circuit comprises a first preamplifier and a first matching circuit, wherein the first preamplifier circuit has a Zᵢₙ approximately equal to
$$\frac{( 50 ) {Z}_{coil}}{{Z}_{in ( PA )}} ,$$
wherein Z_{in(PA)} is the input impedance of the first preamplifier.

11. The MRI coil configuration according to claim 8, wherein the second preamplifier circuit has a Zₒₚₜ₍₂₎ of less than 10% of Z_{coil}.

12. The MRI coil configuration according to claim 8, wherein the second preamplifier circuit has a Zₒₚₜ₍₂₎ of less than 5% of the Z_{coil}.

13. The MRI coil configuration according to claim 1, wherein the first preamplifier circuit has a Zₒₚₜ₍₁₎ and the second preamplifier circuit has a Zₒₚₜ₍₂₎ such that Zₒₚₜ₍₁₎+Zₒₚₜ₍₂₎ is approximately equal to Z_{coil}.

14. The MRI coil configuration according to claim 1, wherein the first preamplifier circuit comprises a first matching circuit and a first preamplifier, wherein the first matching circuit performs a lossless transformation of the first preamplifier's Z_{in(PA)} and Z_{opt(PA)} to the Zᵢₙ₍₁₎ and Zₒₚₜ₍₁₎ of the first preamplifier circuit.

15. The MRI coil configuration according to claim 10, wherein the
$${Z}_{in ( 1 )} \geq \frac{( 0.95 ) ( 50 ) {Z}_{coil}}{{Z}_{in ( PA )}} .$$

16. The MRI coil configuration according to claim 10, wherein the
$${Z}_{in ( 2 )} < \frac{( 0.05 ) ( 50 ) {Z}_{coil}}{{Z}_{in ( PA )}} .$$

17. The MRI coil configuration according to claim 10, wherein Zᵢₙ₍₂₎>Z_{coil}.

18. The MRI coil configuration according to claim 1, further comprising:
a means for creating a first combined signal and a second combined signal, wherein the first combined signal is related to varying E-M fields detected by the coil element, wherein the second combined signal is related to varying E-M fields produced by the coil element.

19. The MRI coil configuration according to claim 18, wherein the first combined signal is a linear combination of the first signal and the second signal.

20. The MRI coil configuration according to claim 18, wherein the second combined signal is a linear combination of the first signal and the second signal.

21. The MRI coil configuration according to claim 19, wherein the second combined signal is a linear combination of the first signal and the second signal.

22. The MRI coil configuration according to claim 18, wherein the means for creating the first combined signal comprises a means for creating the first combined signal via software.

23. The MRI coil configuration according to claim 18, wherein the means for creating the first combined signal comprises a means for creating the first combined signal via hardware.

24. The MRI coil configuration according to claim 1, wherein the first signal is related to varying E-M fields detected by the coil element, wherein the second signal is related to varying E-M fields produced by the coil element.

25. The MRI coil configuration according to claim 1, wherein the first signal is a first current signal, wherein the second signal is a second current signal.

26. The MRI coil configuration according to claim 18, wherein the first combined signal is a first current signal, wherein the second combined signal is a second current signal.

27. The MRI coil configuration according to claim 1, wherein the first signal is a first voltage signal, wherein the second signal is a second voltage signal.

28. The MRI coil configuration according to claim 18, wherein the first combined signal is a first voltage signal, wherein the second combined signal is a second voltage signal.

29. The MRI coil configuration according to claim 1, wherein a portion of the first signal is proportional to the varying E-M fields detected by the coil element.

30. The MRI coil configuration according to claim 1, wherein a portion of the second signal is proportional to the varying E-M fields detected by the coil element.

31. The MRI coil configuration according to claim 18, wherein a portion of the first signal is proportional to the varying E-M fields detected by the coil element.

32. The MRI coil configuration according to claim 18, wherein a portion of the second signal is proportional to the varying E-M fields detected by the coil element.

33. The MRI coil configuration according to claim 29, wherein another portion of the first signal is proportional to the sum of the noise generated by the coil element, the noise generated by the first preamplifier circuit, and the noise generated by the second preamplifier circuit.

34. The MRI coil configuration according to claim 30, wherein another portion of the second signal is proportional to the sum of the noise generated by the coil element, the noise generated by the first preamplifier circuit, and the noise generated by the second preamplifier circuit.

35. The MRI coil configuration according to claim 31, wherein another portion of the first signal is proportional to the sum of the noise generated by the coil element, the noise generated by the first preamplifier circuit, and the noise generated by the second preamplifier circuit.

36. The MRI coil configuration according to claim 32, wherein another portion of the second signal is proportional to the sum of the noise generated by the coil element, the noise generated by the first preamplifier circuit, and the noise generated by the second preamplifier circuit.

37. The MRI coil configuration according to claim 1, wherein the coil element comprises at least one loop of a conductor.

38. The MRI coil configuration according to claim 37, wherein the coil element further comprises:
at least one capacitive element, adjustment of which tunes the resonant frequency of the coil element.

39. The MRI coil configuration according to claim 3, further comprising:
a means for reducing noise in the at least one additional first signal via use of the first signal and the second signal.

40. The MRI coil configuration according to claim 39, further comprising:
a means for reducing noise in the at least one additional first signal via use of the first signal and the second signal.

41. An RF coil configuration, comprising:
a coil element;
a first preamplifier circuit; and
a second preamplifier circuit,
wherein the first preamplifier circuit outputs a first signal,
wherein the second preamplifier circuit outputs a second signal.
